(19) United States
(12) Patent Application Publication
(10) Pub. No.: US 2025/0098256 A1
(43) Pub. Date: Mar. 20, 2025

(54) SELF-ALIGNED BACKSIDE INTERCONNECT

(71) Applicant: QUALCOMM Incorporated, San Diego, CA (US)

(72) Inventors: Yan SUN, San Diego, CA (US); Shreesh NARASIMHA, Charlotte, NC (US)

(21) Appl. No.: 18/469,465

(22) Filed: Sep. 18, 2023

(51) Int. Cl. H01L 29/66; H01L 21/8234; H01L 27/088; H01L 29/06; H01L 29/08; H01L 29/423; H01L 29/775; H01L 29/786

(52) U.S. Cl. CPC H10D 64/017; H10D 30/014; H10D 30/43; H10D 30/6735; H10D 30/6757; H10D 62/121; H10D 62/151; H10D 84/0128; H10D 84/013; H10D 84/0158; H10D 84/038; H10D 84/83

(57) ABSTRACT

Disclosed are techniques for a semiconductor structure. In an aspect, a semiconductor structure includes a gate stack extending along a first direction in a front portion of the semiconductor structure, the gate stack including a first gate structure; a first channel structure disposed through the first gate structure and extending along a second direction; a first source/drain (S/D) structure adjacent the first gate structure and electrically coupled to the first channel structure; a backside dielectric layer disposed in a back portion of the semiconductor structure opposing the front portion; and a backside conductive structure in contact with the first S/D structure and disposed at least partially in the back portion of the semiconductor structure and through the backside dielectric layer. The backside conductive structure has a length in the first direction greater than a width of the first channel structure in the first direction.

### TECHNICAL FIELD

The present disclosure generally relates to a semiconductor structure of an integrated circuit device, and more particularly, to a semiconductor structure with self-aligned backside interconnects.

### BACKGROUND

Integrated circuit (IC) technology has achieved great strides in advancing computing power through miniaturization of electrical components. An IC device may be implemented in the form of an IC chip that has a set of circuits integrated thereon, including a plurality of active and passive components (e.g., transistors, diodes, capacitors, inductors, and/or resistors) and layers of contacts and interconnects above the active and passive components. In some aspects, the contacts and interconnects of an IC device are formed on the active and passive components from a front side of the IC device. As the sizes of the IC devices and the sizes of the components formed thereon become smaller, and the available area for forming the contacts and interconnects also become smaller. As such, the routing complexity and/or of parasitic resistance and capacitance of the contacts and interconnects may increase and thus the manufacturing cost or the performance of the IC device may be negatively impacted.

Accordingly, in order to further reduce the routing complexity and/or reduce parasitic resistance and capacitance, there is a need for improved structures or manufacturing methods of the contacts and interconnects.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a semiconductor structure includes a gate stack extending along a first direction in a front portion of the semiconductor structure, the gate stack including a first gate structure; a first channel structure disposed through the first gate structure and extending along a second direction from a first side of the first gate structure to a second side of the first gate structure; a first source/drain (S/D) structure adjacent the first gate structure and electrically coupled to the first channel structure; a backside dielectric layer disposed in a back portion of the semiconductor structure opposing the front portion; and a backside conductive structure in contact with the first S/D structure and disposed at least partially in the back portion of the semiconductor structure and through the backside dielectric layer, wherein the backside conductive structure extends along the first direction and has a length in the first direction greater than a width of the first channel structure in the first direction.

In an aspect, a method of manufacturing a semiconductor structure includes forming a first channel structure; forming a first source/drain (S/D) structure electrically coupled to the first channel structure; forming a first gate structure included in a gate stack extending along a first direction in a front portion of the semiconductor structure, the first channel structure disposed through the first gate structure and extending along a second direction from a first side of the first gate structure to a second side of the first gate structure, and the first S/D structure adjacent the first gate structure; forming a backside dielectric layer in a back portion of the semiconductor structure opposing the front portion; removing a sacrificial structure in the backside dielectric layer and removing a portion of an epitaxial stop layer under the first S/D structure to define an opening; and forming a backside conductive structure based on the opening, the backside conductive structure being in contact with the first S/D structure and disposed at least partially in the back portion of the semiconductor structure and through the backside dielectric layer, wherein the backside conductive structure extends along the first direction and has a length in the first direction greater than a width of the first channel structure in the first direction.

In an aspect, an electronic device includes an integrated circuit device including a semiconductor structure, and the semiconductor structure comprising: a gate stack extending along a first direction in a front portion of the semiconductor structure, the gate stack including a first gate structure; a first channel structure disposed through the first gate structure and extending along a second direction from a first side of the first gate structure to a second side of the first gate structure; a first source/drain (S/D) structure adjacent the first gate structure and electrically coupled to the first channel structure; a backside dielectric layer disposed in a back portion of the semiconductor structure opposing the front portion; and a backside conductive structure in contact with the first S/D structure and disposed at least partially in the back portion of the semiconductor structure and through the backside dielectric layer, wherein the backside conductive structure extends along the first direction and has a length in the first direction greater than a width of the first channel structure in the first direction.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1 is a top view of a portion of a semiconductor structure of an integrated circuit (IC) device, according to aspects of the disclosure.

FIGS. 2A and 2B are top views of a portion of a semiconductor structure of an IC device, with emphasis of elements at different vertical regions thereof, according to aspects of the disclosure.

FIG. 3A is a top view of a portion of a semiconductor structure of an IC device, according to aspects of the disclosure.

FIG. 3B is a top view of a portion of a semiconductor structure of an IC device, according to aspects of the disclosure.

FIGS. 3C and 3D are cross-sectional views of a portion of the semiconductor structure of FIG. 3B, according to aspects of the disclosure.

FIGS. 4A and 4B illustrate a manufacturing process for manufacturing a semiconductor structure, according to aspects of the disclosure.

FIGS. 5A-5J illustrate structures at various stages of manufacturing a semiconductor structure of FIGS. 3B-3C, according to aspects of the disclosure.

FIGS. 6A-6C illustrate some advantages of the present disclosure based on other structure examples, according to aspects of the disclosure.

FIG. 7 illustrates a method for manufacturing a semiconductor structure, according to aspects of the disclosure.

FIG. 8 illustrates a mobile device example, according to aspects of the disclosure.

FIG. 9 illustrates various electronic devices that may be integrated with IC devices, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

Various aspects relate generally to a semiconductor structure of an integrated circuit device and a manufacturing method of making the semiconductor structure. Some aspects more specifically relate to a semiconductor structure with self-aligned backside interconnects or contacts.

Particular aspects of the subject matter described in this disclosure can be implemented to realize one or more of the following potential advantages. In some examples, by forming the backside conductive structures based on a self-aligned scheme, the contact resistance may be reduced due to the increased size of the self-aligned backside conductive structures and/or the process margin for forming the self-aligned backside conductive structures may be increased.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

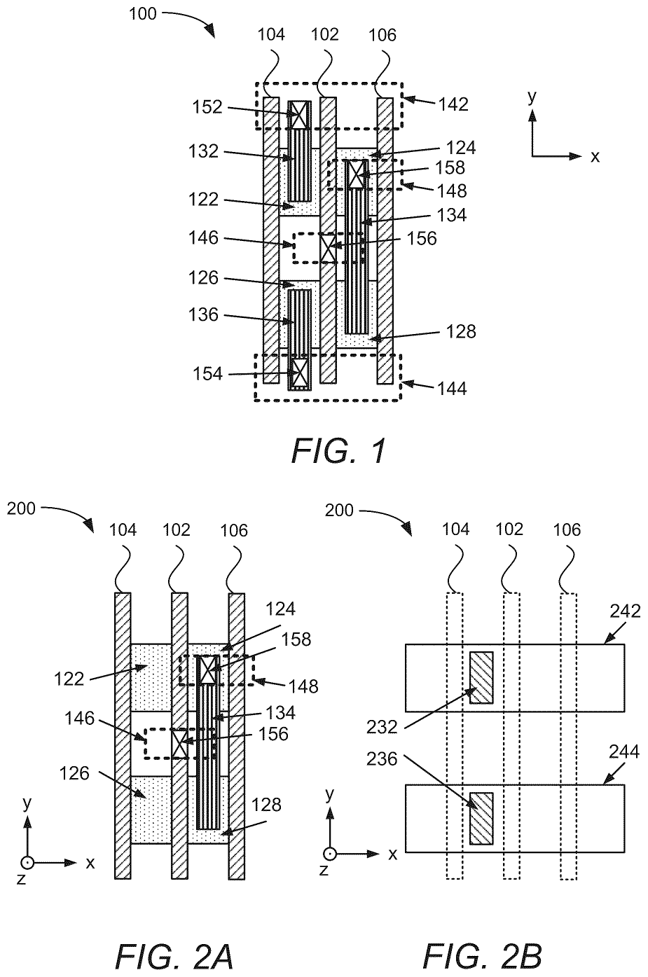

FIG. 1 is a top view of a portion of a semiconductor structure 100 of an integrated circuit (IC) device, according to aspects of the disclosure. In some aspects, FIG. 1 merely shows some elements of the semiconductor structure 100 for illustration purposes, and other elements above and/or below the elements shown in FIG. 1 may be disposed in the IC device but not shown in FIG. 1.

As shown in FIG. 1, the semiconductor structure 100 includes gate stacks 102, 104, and 106 extending along a first direction (e.g., the y direction), a source/drain (S/D) structure 122 between the gate stacks 102 and 104, an S/D structure 124 between the gate stacks 102 and 106, an S/D structure 126 between the gate stacks 102 and 104, and an S/D structure 128 between the gate stacks 102 and 106. The S/D structure 122 and the S/D structure 126 are disposed apart from each other in the first direction, and the S/D structure 124 and the S/D structure 128 are disposed apart from each other in the first direction.

A portion of the gate stack 102 adjacent the S/D structure 122 and the S/D structure 124 may be configured as a first gate structure, and a first channel structure may be formed through the first gate structure in a second direction (e.g., the x direction). The S/D structure 122 and the S/D structure 124 may be electrically coupled to the first channel structure. Also, a portion of the gate stack 102 adjacent the S/D structure 126 and the S/D structure 128 may be configured as a second gate structure, and a second channel structure may be formed through the second gate structure in the second direction. The S/D structure 126 and the S/D structure 128 may be electrically coupled to the second channel structure. In some aspects, the S/D structure 122 and the S/D structure 124 may have a first doping type, and the S/D structure 126 and the S/D structure 128 may have a second doping type different from the first doping type.

In some aspects, the first gate structure, the first channel structure, the S/D structure 122, and the S/D structure 124 may be configured as a first transistor of a first type; and the second gate structure, the second channel structure, the S/D structure 126, and the S/D structure 128 may be configured as a second transistor of a second type. In some aspect, the gate stacks 104 and 106 may be configured as dummy gates that are to be biased to electrically separate the S/D structures 122, 124, 126, and 128 from neighboring S/D structures (not shown).

As shown in FIG. 1, the semiconductor structure 100 includes a contact 132 electrically coupled to the S/D structure 122, a contact 134 electrically coupled to the S/D structure 124 and the S/D structure 128, and a contact 136 electrically coupled to the S/D structure 126. The semiconductor structure 100 includes a first conductive structure 142, a second conductive structure 144, a third conductive structure 146, and a fourth conductive structure 148 above the gate stacks 102, 104, and 106 and the contacts 132, 134, and 136. The semiconductor structure 100 further includes a contact 152 electrically coupling the contact 132 to the conductive structure 142, a contact 154 electrically coupling the contact 136 to the conductive structure 144, a contact 156 electrically coupling the gate stack 102 to the conductive structure 146, and a contact 158 electrically coupling the contact 134 to the conductive structure 148.

In some aspects, the first conductive structure 142 may be a first power line configured to carry a first power voltage (e.g., VDD), and the second conductive structure 144 may be a second power line configured to carry a second power voltage (e.g., VSS or ground). In some aspects, the conductive structure 146 may be a signal line configured to carry a gate voltage for controlling the first gate structure of the first transistor and the second gate structure of the second transistor. In some aspects, the conductive structure 148 may be a signal line configured to carry a S/D voltage at the S/D structure 124 of the first transistor and the S/D structure 128 of the second transistor. In some aspects, the portion of the semiconductor structure 100 shown in FIG. 1 forms an inverter and may be used as a standard cell of an inverter for manufacturing the IC device.

FIGS. 2A and 2B are top views of a portion of a semiconductor structure 200 of an IC device, with emphasis of elements at different vertical regions thereof, according to aspects of the disclosure. In particular, the elements shown in FIG. 2A shows the elements that may be above the elements shown in FIG. 2B in a vertical direction (e.g., the z direction corresponding to a direction leaving the plane of the drawing sheet). In some aspects, FIGS. 2A and 2B merely show some elements of the semiconductor structure 200 for illustration purposes, and other elements above and/or below the elements shown in FIGS. 2A and 2B may be disposed but not shown in FIGS. 2A and 2B. Moreover, the elements that are the same or similar to those in FIG. 1 are given the same reference numbers, and detailed description thereof may be omitted.

As shown in FIG. 2A, compared to the semiconductor structure 100, the semiconductor structure 200 does not include the contacts 132 and 136, the conductive structures 142 and 144, and the contacts 152 and 154. In some aspects, compared to the semiconductor structure 100, the contacts and interconnects formed based on these omitted elements may be replaced by backside contacts and backside interconnects. In some aspects, the backside contacts and the backside interconnects may correspond to the contacts and interconnects disposed below the S/D structures and/or gate stacks in the vertical direction and may be formed from the back side of the semiconductor structure.

As shown in FIG. 2B, the semiconductor structure 200 includes a backside contact 232 electrically coupling the S/D structure 122 of the first transistor to a backside conductive structure 242, and a backside contact 236 electrically coupling the S/D structure 128 of the second transistor to a backside conductive structure 244. In some aspects, the backside conductive structure 242 may be configured to carry the first power voltage (e.g., VDD), and the backside conductive structure 244 may be configured to carry the second power voltage (e.g., VSS or ground).

In some aspects, scaling of logic components may become ineffective due to slowed pitch scaling and lack of material breakthrough. In some aspects, front-side only technology (e.g., the example illustrated with reference to FIG. 1) or power via buried power rail may have higher middle-of-line (MOL) capacitance, which may limit the achievable level of power reduction.

In some aspects, one of promising future directions for continued scaling is based on a gate-all-around backside power distribution network (GAA-BSPDN) technology (e.g., the example illustrated with reference to FIGS. 2A and 2B), where the contacts of the S/D structures (i.e., S/D contacts or diffusion contacts) and/or local interconnects may be formed directly from the back side of the semiconductor structure. In some aspects, a diffusion contact formed from the back side may be referred to as a backside contact (BSC), and a local interconnect formed from the back side may be referred to as a backside contact local interconnect (BSCLI). In some aspects, with more than half of the diffusion contacts and/or local interconnects being implemented as BSCs and/or BSCLIs, gate-to-contact parasitic capacitance may be greatly reduced. In some aspects, the amount of capacitance improvement may be significant, e.g., equivalent to about half of the whole manufacturing technology node reduction. In some aspects, as the pitch or critical dimension of the elements continue to shrink, it may be difficult to properly overlay the BSCs and/or BSCLIs with the S/D structures (e.g., manufactured as epitaxial process from the front side).

Accordingly, the present application further describes methods of manufacturing the BSCLIs as self-aligned contacts to resolve the aforementioned overlay issue. In some aspects, a deep trench may be formed from the front side based on where the BSC or BSCLI would be formed, and may be filled from the front side with a sacrificial material that may be highly selective over silicon (Si), silicon germanium (SiGe), and/or interlayer dielectric (ILD) oxide. In some aspects, once the wafer for forming the IC device is flipped over and thinned down, the sacrificial material may be exposed, removed, and back-filled with conductive materials (e.g., tungsten (W) and/or ruthenium (Ru)) in order to form a BSCLI.

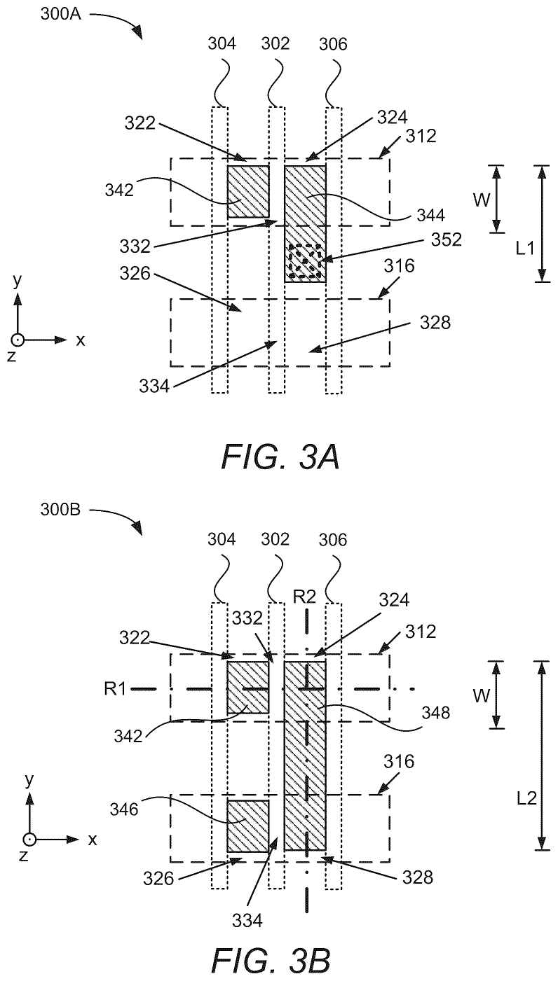

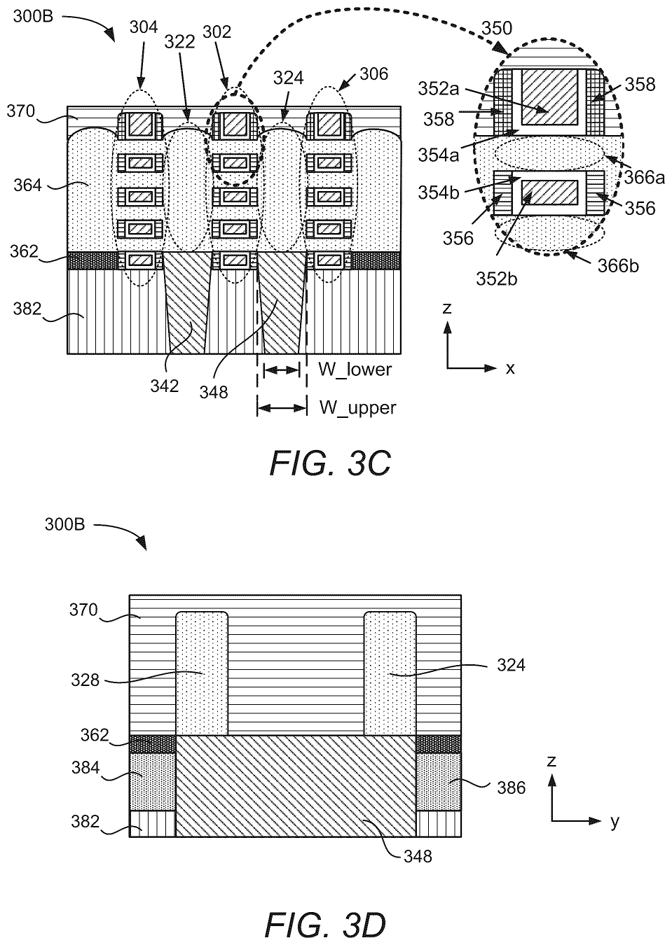

FIG. 3A is a top view of a portion of a semiconductor structure 300A of an IC device, according to aspects of the disclosure. In some aspects, the elements shown in FIG. 3A may be disposed under various elements similar to the elements shown in FIG. 2A. In some aspects, the semiconductor structure 300A includes gate stacks 302, 304, and 306 that may correspond to the gate stacks 102, 104, and 106 in FIG. 1 or FIG. 2A.

In FIG. 3A, dotted blocks are used to indicate active areas 312 and 316 where the corresponding S/D structures and channel structures may be formed over the elements shown in FIG. 3A. In some aspects, a portion of the active area 312 between the gate stacks 302 and 304 may correspond to an S/D structure 322 of a first transistor; and a portion of the active area 312 between the gate stacks 302 and 306 may correspond to another S/D structure 324 of the first transistor. Also, a portion of the gate stack 302 overlapping the active area 312 may correspond to a first gate structure and a first channel structure 332 of the first transistor. In some aspects, a portion of the active area 316 between the gate stacks 302 and 304 may correspond to an S/D structure 326 of a second transistor; and a portion of the active area 316 between the gate stacks 302 and 306 may correspond to another S/D structure 328 of the second transistor. Also, a portion of the gate stack 302 overlapping the active area 316 may correspond to a second gate structure and a second channel structure 334 of the second transistor. In some aspect, the gate stacks 304 and 306 may be configured as dummy gates that are to be biased to electrically separate the S/D structures 322, 324, 326, and 328 from neighboring S/D structures.

In some aspects, the semiconductor structure 300A may include a backside conductive structure (e.g., a BSC) 342 and a backside conductive structure (e.g., a BSC) 344. The backside conductive structure 342 and the backside conductive structure 344 may be self-aligned contacts according to the present application. In some aspects, the backside conductive structure 342 is electrically coupled to the S/D structure 322, and the backside conductive structure 344 is electrically coupled to the S/D structure 324. In some aspects, the backside conductive structure 344 may extend along the first direction (e.g., the y direction) beyond the active area 312, such that a length L1 of the conductive structure 344 in the first direction may be greater than a width W of the first channel structure 332 in the first direction. In some aspects, the backside conductive structure 344 may extend along the first direction at least from the S/D structure 324 to a middle point between the S/D structure 324 and the S/D structure 328. In some aspects, a backside via 352 may be formed under the backside conductive structure 344 for electrically coupling the backside conductive structure 344 to a metallization structure below the backside conductive structure 344. In some aspects, the backside via 352 may be offset from and non-overlapping with the first channel structure 332 in the first direction.

FIG. 3B is a top view of a portion of a semiconductor structure 300B of an IC device, according to aspects of the disclosure. In some aspects, the elements shown in FIG. 3B may be disposed under various elements similar to the elements shown in FIG. 2A. In some aspects, the semiconductor structure 300B includes gate stacks 302, 304, and 306 that may correspond to the gate stacks 102, 104, and 106 in FIG. 1 or FIG. 2A. In some aspects, the semiconductor structure 300B may be a variation of the semiconductor structure 300A. Elements in FIG. 3B that are the same or similar to those shown in FIG. 3A are given the same reference numbers, and detailed description thereof may be omitted.

As shown in FIG. 3B, the semiconductor structure 300B may include a backside conductive structure (e.g., a BSC) 342, a backside conductive structure (e.g., a BSC) 346, and a backside conductive structure (e.g., a BSCLI) 348. The backside conductive structures 342, 346, and 348 may be self-aligned contacts according to the present application. In some aspects, the backside conductive structure 342 is electrically coupled to the S/D structure 322, the backside conductive structure 346 is electrically coupled to the S/D structure 326, and the backside conductive structure 348 is electrically coupled to the S/D structures 324 and 328.

In some aspects, the backside conductive structure 348 may extend along the first direction (e.g., the y direction) beyond the active area 312, such that a length L2 of the conductive structure 348 in the first direction may be greater than a width W of the first channel structure 332 in the first direction. In some aspects, the backside conductive structure 344 may extend along the first direction at least from the S/D structure 324 to the S/D structure 328 and is in contact with the S/D structures 324 and 328.

Cross-sectional views of the semiconductor structure 300B along a cut line R1 and a cut line R2 are presented in FIGS. 3C and 3D. In particular, FIG. 3C is a cross-sectional view of a portion of the semiconductor structure 300B along the cut line R1. Also, FIG. 3D is a cross-sectional view of a portion of the semiconductor structure 300B along the cut line R2. Elements in FIGS. 3C and 3D that are the same or similar to those in FIG. 3B are given the same reference numbers, and detailed description thereof may be omitted.

As shown in FIG. 3C, the semiconductor structure 300B includes gate stacks 302, 304, and 306. An enlarged area 350 showing the details of a portion of the gate stack 302. In some aspects, the gate stacks 304 and 306 may have a configuration similar to the configuration of the gate stack 302. As shown in FIG. 3C, the gate stack 302 may include five gate portions each including a respective gate electrode (also called “gate metal” or “gate conductor”) (e.g., gate electrode 352a or 352b) and a respective gate dielectric structure (e.g., gate dielectric structure 354a or 354b). In this disclosure, all the gate electrodes in a gate stack may be collectively referred to as a gate electrode structure. In some aspects, a top gate portion of the gate stack 302 may include gate spacers 358 on sidewalls of the gate dielectric structure 354a. In some aspects, the gate portions of the gate stack 302 other than the top gate portion may include inner spacers (e.g., inner spacers 356) on sidewalls of the respective gate dielectric structure (e.g., gate dielectric structure 354b).

The semiconductor structure 300B may include an epitaxial stop layer 362. In some aspects, a lower surface of the epitaxial stop layer 362 may be at about the same level of a lower surface of the gate structures of the gate stacks 302, 304, and 306. The semiconductor structure 300B may further include an epitaxial layer 364. The portion of the epitaxial layer 364 between the gate stacks 302 and 304 may define the S/D structure 322; and the portion of the epitaxial layer 364 between the gate stacks 302 and 306 may define the S/D structure 324. Moreover, the portions of the gate stacks 302, 304, and/or 306 between adjacent gate portions may be configured as channel members (e.g., channel members 366a and 366b). In this disclosure, all the channel members in a gate stack may be collectively referred to as a channel structure. In some aspects, the channel members may comprise a plurality of nanowires or nanosheets.

As shown in FIG. 3C, the semiconductor structure 300B may include a front side dielectric layer 370 (e.g., a front side ILD layer) on the gate stacks 302, 304, and 306 and the epitaxial layer 364. In some aspects, for the convenience of illustration, the elements that are at or above the lower surface of the epitaxial stop layer 362 and/or the lower surface of the gate structures of the gate stacks 302, 304, and 306 may be referred to as a front portion of the semiconductor structure 300B; and the elements that are below the lower surface of the epitaxial stop layer 362 and/or the lower surface of the gate structures of the gate stacks 302, 304, and 306 may be referred to as a back portion of the semiconductor structure 300B opposing the front portion.

As shown in FIG. 3C, the semiconductor structure 300B may further include a backside dielectric layer 382 (e.g., a backside ILD layer) in the back portion of the semiconductor structure 300B. The backside conductive structures 342 and 348 may be disposed at least partially in the back portion of the semiconductor structure and through the backside dielectric layer 382. Moreover, as shown in FIG. 3D, the backside conductive structure 348 may extend along the first direction (e.g., the y direction) and electrically coupled to the S/D structures 324 and 328. As shown in FIG. 3D, isolation structures 384 and 386 (e.g., shallow trench isolation (STI) structures) may be disposed under the epitaxial stop layer 362 and/or the front side dielectric layer 370 in the area outside the active areas 312 and 316 in FIG. 3B.

As shown in FIGS. 3C, in some aspects, an upper portion of the backside conductive structure (e.g., the backside conductive structure 348) may be in contact with a bottom inner spacer of a gate structure (e.g., the gate structure of the gate stack 302) and a bottom inner spacer of another gate structure (e.g., the gate structure of the gate stack 306 that is offset from the gate structure of the gate stack 302 in the x direction). In some aspects, a first width (e.g., width W_upper) of an upper portion of the backside conductive structure (e.g., the backside conductive structure 348) in the second direction may be greater than a second width (e.g., width W_lower) of a lower portion of the backside conductive structure in the second direction. In some aspects, the backside conductive structures may comprise tungsten, cobalt, molybdenum, ruthenium, or a combination thereof.

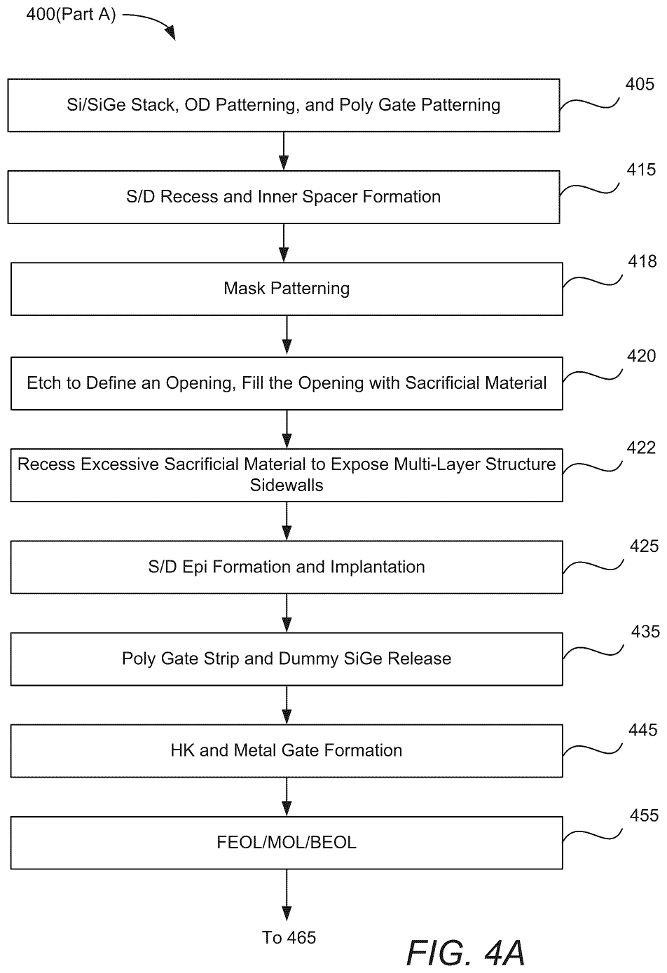

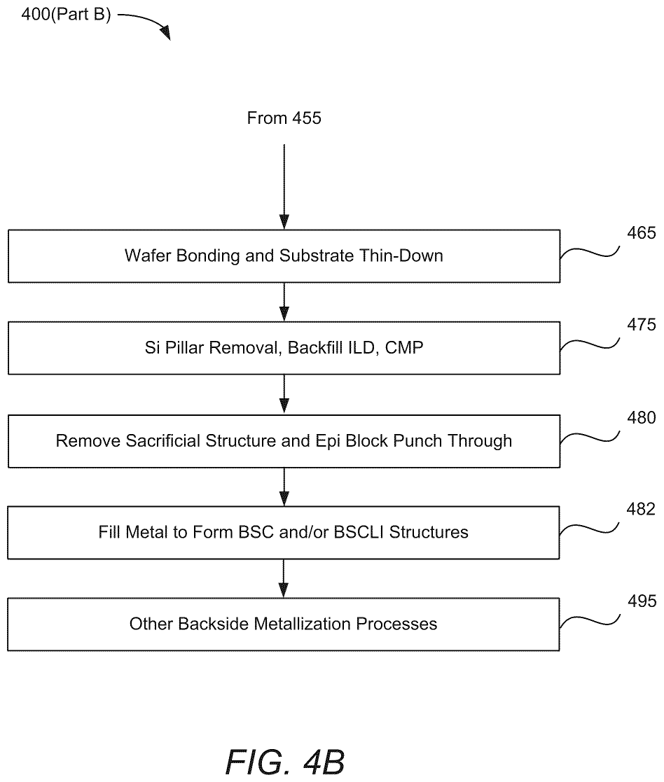

FIGS. 4A and 4B illustrate a manufacturing process 400 for manufacturing a semiconductor structure (e.g., the semiconductor structure 300A in FIG. 3A and/or the semiconductor structure 300B in FIGS. 3B-3D), according to aspects of the disclosure. In some aspects, the processing stages shown in FIG. 4A (labeled as “Part A” of the manufacturing process 400) may correspond to front-side processing of the semiconductor structure, as these stages may correspond to processes performed from a front side of a wafer on which the semiconductor structure is formed. In some aspects, the processing stages shown in FIG. 4B (labeled as “Part B” of the manufacturing process 400) may correspond to back-side processing of the wafer, as these stages may correspond to processes performed from a back side of the wafer opposing the front side of the wafer.

At stage 405, a multi-layer structure may be formed on a substrate of a wafer. In some aspects, the multi-layer structure may include layers of different silicon materials stacked one over another. In some aspects the multi-layer structure may include layers of silicon (Si) and silicon germanium (SiGe) stacked one over another as a Si/SiGe stack.

At stage 405, an active area of the semiconductor structure may be defined based on an oxide diffusion (OD) pattern. In some aspects, an OD patterning process may be performed on the multi-layer structure (e.g., the Si/SiGe stack) to shape the multi-layer structure into a fin-like structure. At stage 405, a layer of polysilicon material may be formed on the fin-like structure, and a poly gate patterning process may be performed on the layer of polysilicon material to form a patterned polysilicon structure on the fin-like structure. In some aspects, the patterned polysilicon structure may extend along a first direction (e.g., the y direction in FIGS. 3A-3D). In some aspects, a polysilicon gate structure may be formed based on the patterned polysilicon structure and may further include outer spacers formed on both sides of the patterned polysilicon structure in a second direction (e.g., the x direction in FIGS. 3A-3D).

At stage 415, a source/drain (S/D) recess process is performed on the fin-like structure using at least the polysilicon gate structure as a mask. The resulting structure after the S/D recess process may include a trimmed multi-layer structure substantially flush with the polysilicon gate structure on the sides in the second direction. In some aspects, an inner spacer formation process is performed based on partially and selectively removing a portion of the multi-layer structure (e.g., selectively removing SiGe over Si) exposed in the second direction and filling the removed portion of the multi-layer structure with a dielectric material to form a plurality of inner spacers.

At stage 418, a mask patterning process is performed to form a resist pattern with an opening based on the positions where the backside conductive structures may be formed. As the backside conductive structures may be formed as self-aligned contact structures, the positions where the backside conductive structures may be defined based on the combination of the resist pattern and the polysilicon gate structure.

At stage 420, an etching process is performed using the resist pattern and the polysilicon gate structure as a mask to define an opening corresponding to the positions where the backside conductive structures may be formed. At stage 420, the opening is further filled with a sacrificial material. At stage 422, the portion of the filled sacrificial material that may cover the sidewalls of the trimmed multi-layer structure may be removed to the extent that will not hinder to subsequent electrical coupling to the channel members (e.g., to expose at least the sidewalls of the trimmed multi-layer structure not covered by the inner spacers).

At stage 425, an S/D epi formation process is performed to form epitaxially grown structures on both sides of the polysilicon gate structure in the second direction. In some aspects, the epitaxially grown structures may include Si. In some aspects, one or more implantation processes may be performed on the epitaxially grown structures to convert the epitaxially grown structures into S/D structures. In some aspects, an epitaxial stop layer may be formed before forming the epitaxially grown structures.

At stage 435, a poly gate strip process may be performed on the polysilicon gate structure to remove at least the polysilicon portion of the polysilicon gate structure. Afterwards, a removal process may be performed to remove the same material of the multi-layer structure removed at stage 415, which converts the multi-layer structure into a channel structure that may include one or more channel members. In some aspects, the multi-layer structure is a Si/SiGe stack, and SiGe is removed at stage 435 (also referred to as a dummy SiGe release process). After stage 435, an opening between the outer spacers and the inner spacers may be defined, with the one or more channel members passing through the opening from side to side in the second direction.

At stage 445, a high dielectric constant (high-k or HK) metal gate structure is formed in the opening from stage 435 and surrounding the one or more channel members. In some aspects, the HK metal gate structure includes a gate electrode structure and one or more gate dielectric structures between the gate electrode structure and the respective one or more channel members. In some aspects, the one or more gate dielectric structures may include a dielectric material or a dielectric structure that corresponds to a dielectric constant greater than a dielectric constant of silicon (hence referred to as HK).

At stage 455, one or more of a front end of line (FEOL) process, a middle of line (MOL) process, or back end of line (BEOL) process may be performed on the resulting structure of stage 445 in order to form a plurality layers of metallization structures. In some aspects, the FEOL process may correspond to forming conductive vias or contacts on the electrical components in order to prepare the electrical components for interconnection. In some aspects, the MOL process may be performed after the FEOL process and may correspond to forming conductive vias and conductive lines for local interconnections among neighboring electrical components. In some aspects, the BEOL process may be performed after the MOL process and may correspond to forming conductive vias and conductive lines for interconnections among groups of electrical components. In some aspects, the MOL process may be omitted, and the local interconnections may be formed based on the FEOL process, the BEOL process, or both.

After the front-side processing of the semiconductor structure as shown in FIG. 4A, the back-side processing of the semiconductor structure is shown in FIG. 4B.

At stage 465, a carrier may be attached to the front side of the wafer from stage 455 during a wafer bonding process. The wafer with carrier attached thereon may be flipped upside down so the substrate on the back side of the wafer now may face up. Afterwards, a substrate thin-down process may be performed to remove at least a portion of the substrate of the wafer.

At stage 475, the remaining of the substrate material may be further, selectively removed during a silicon pillar removal process and leaving structures such as etch stop layers, STI structures, and/or other structures (such as a placeholder or sacrificial via structure). Afterwards, a backside ILD layer may be formed by filling an ILD material from the back side of the wafer. In some aspects, a further chemical-mechanical polishing (CMP) process may be performed to trim the thickness of the backside ILD layer.

At stage 480, the sacrificial structures formed at stage 422 may be exposed after stage 475 and may be removed from the back side of the wafer. At stage 480, a portion of the epitaxial stop layer under the S/D structures and exposed after the removal of the sacrificial structures may be further removed based on an epi stop punch through process. After stage 480, backside openings thus may be defined based on the removal of the sacrificial structures and the removal of the portion of the epitaxial stop layer under the S/D structures.

At stage 482, the backside opening from stage 480 may be filled with a conductive or metallic material to form the backside conductive structures, such as the BSC and/or the BSCLI structures illustrated in FIGS. 3A-3D.

At stage 495, other backside metallization processes may be performed to form additional metallization layers, including one or more power lines and/or one or more signal lines. In some aspects, one or more conductive pads may be formed, where a resulting integrated circuit device based on the semiconductor structure described herein may be attached to another integrated circuit device, an interposer, or a packaging substrate through the one or more conductive pads.

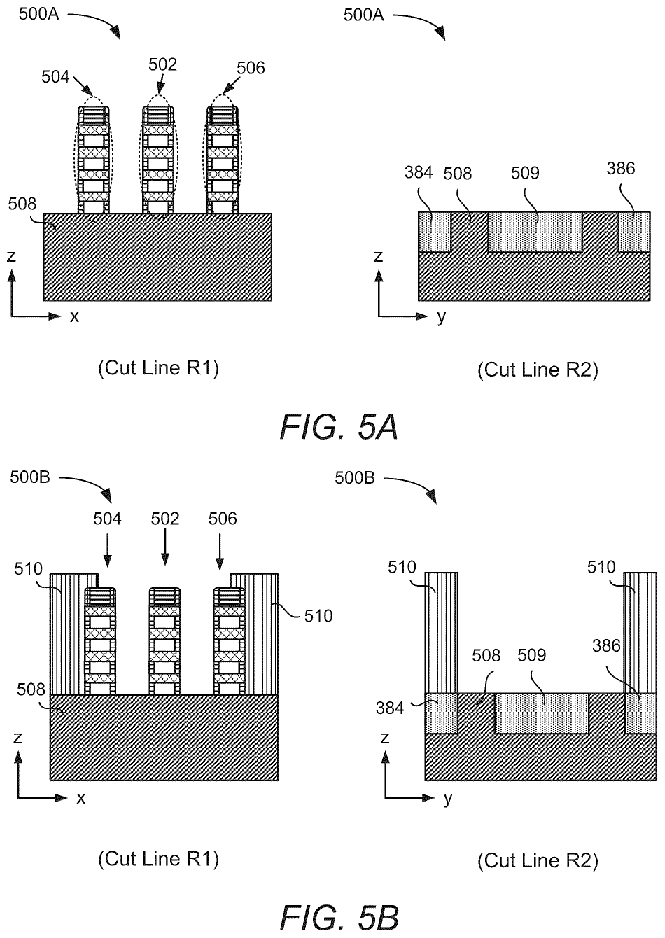

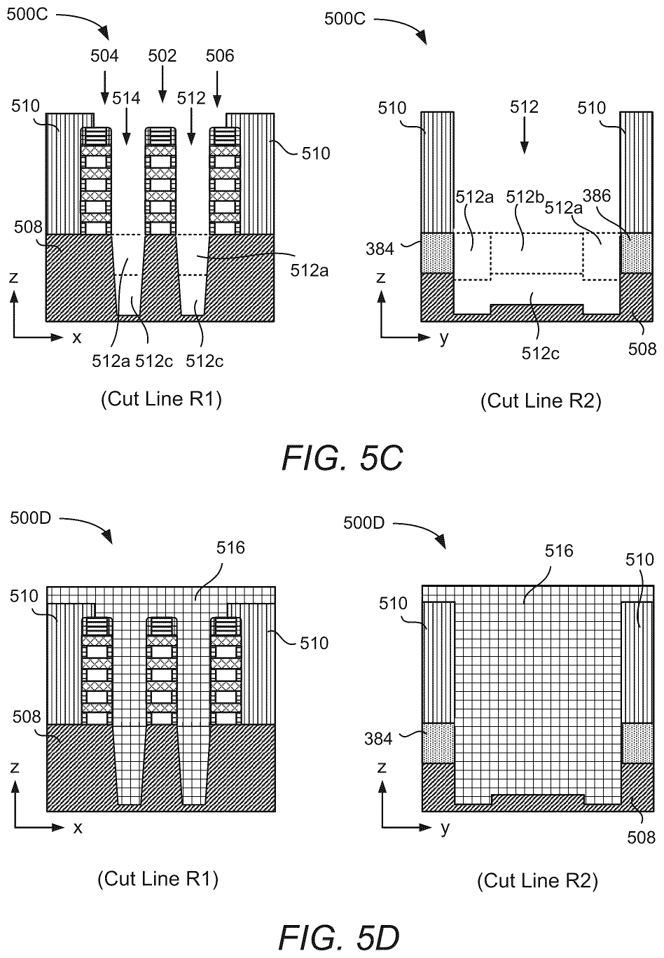

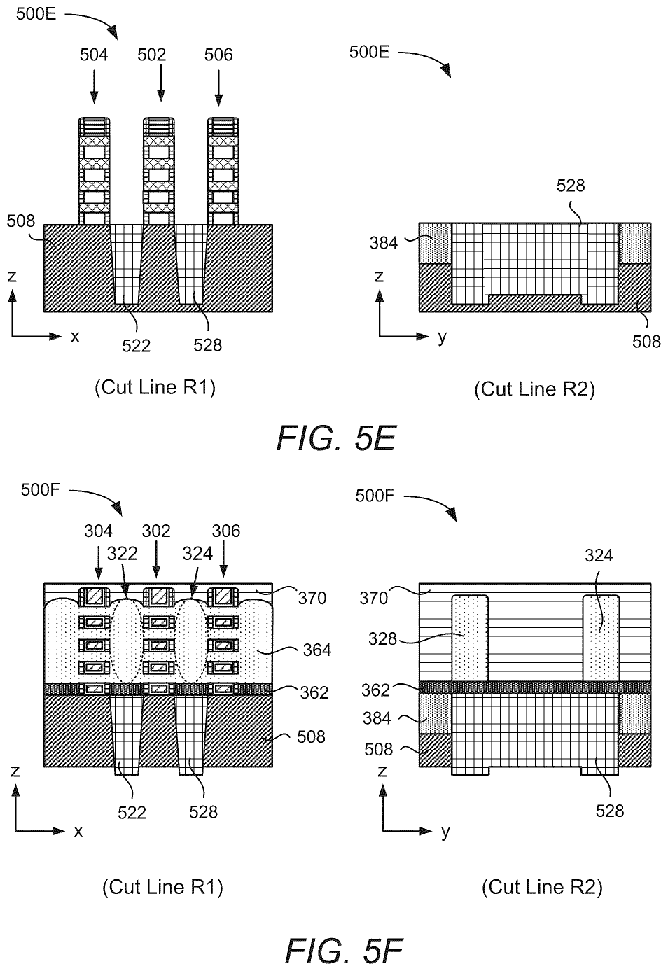

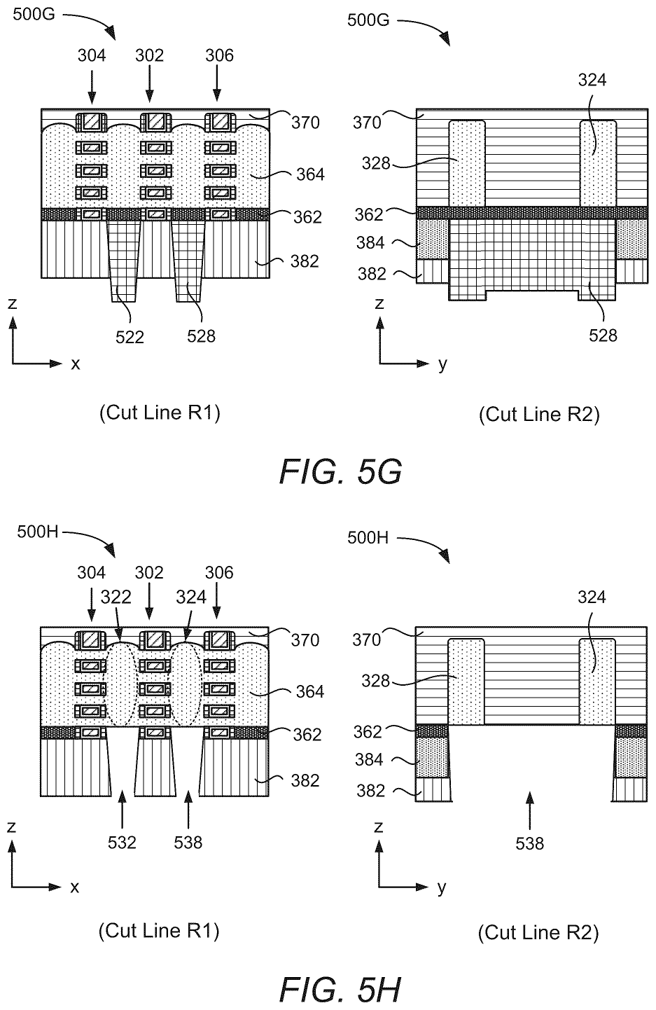

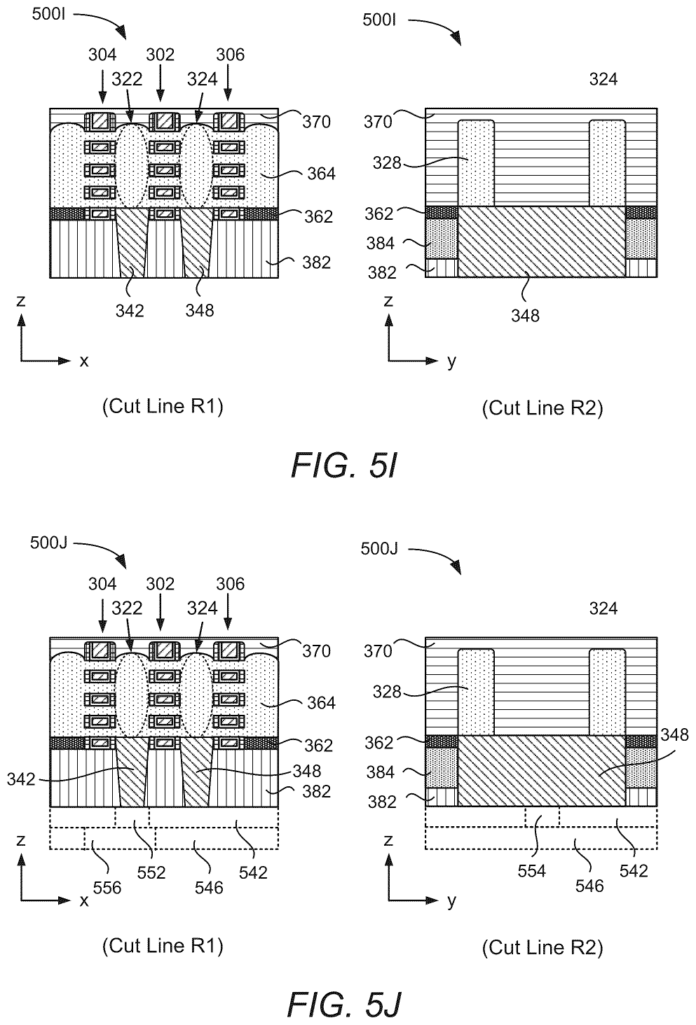

FIGS. 5A-5J illustrate structures at various stages of manufacturing a semiconductor structure of FIGS. 3B-3D, according to aspects of the disclosure. Each one of FIGS. 5A-5J includes a cross-sectional view (denoted “Cut Line R1”) on the left that is taken along a cut line corresponding to the cut line R1 in FIG. 3B; and a cross-sectional view (denoted “Cut Line R2”) on the right that is taken along a cut line corresponding to the cut line R2 in FIG. 3B. The elements illustrated in FIGS. 5A-5J that are the same or similar to those of FIGS. 3B-3D are given the same reference numbers, and the detailed description thereof may be omitted.

As shown in FIG. 5A, a structure 500A is provided. The structure 500A includes three gate stacks 502, 504, and 506 on a substrate 508. Also, STI structures 384, 386, and 509 may be embedded in the substrate 508 in the area outside the active areas 312 and 316 in FIG. 3B. In some aspects, the gate stacks 502, 504, and 506 may correspond to the resulting structure of the gate stacks at stage 415 in FIG. 4A.

As shown in FIG. 5B, a structure 500B is formed based on the structure 500A by forming a resist pattern 510 that defines an opening based on the positions where the backside conductive structures may be formed. In some aspects, the resist pattern 510 may be formed by first forming a photoresist material over the structure 500A, then performing a lithographic process to develop an exposed portion of the photoresist material, and either removing the exposed portion or an exposed portion of the photoresist material (depending on the type of the photoresist material and/or the removal process) to form the resist pattern 510. In some aspects, the structure 500B may correspond to the resulting structure at stage 418 in FIG. 4A.

As shown in FIG. 5C, a structure 500C is formed based on the structure 500B by forming an etching process based using the gate stacks 502, 504, and 506 and the resist pattern 510 as a mask to define openings 512 and 514 corresponding to the positions where the backside conductive structures (e.g., the backside conductive structures 342 and 348, respectively) may be formed. In some aspects, the etching process may include multiple steps, including a first step removing a portion of the substrate 508 (e.g., corresponding to region 512a), a second step removing the STI structure 509 (e.g., corresponding to region 512b), and a third step further extending the opening (e.g., corresponding to region 512c). In some aspects, the etching process may include a step of non-selective etching to etch deep enough into the substrate 508 under the STI structure 509 (e.g., forming the regions 512a, 512b, and 512c in a single, non-selective etching step). In some aspects, the structure 500C may correspond to the resulting structure of the first half of stage 420 in FIG. 4A.

As shown in FIG. 5D, a structure 500D is formed based on the structure 500C by filling a sacrificial material into the openings 512 and 514 to form the filled sacrificial material 516. In some aspects, the sacrificial material may have a preferred selectivity over a dielectric material (e.g., silicon oxide) for forming the backside dielectric layer (e.g., the backside dielectric layer 382) during a subsequent sacrificial material removal process (e.g., at stage 480). In some aspects, the sacrificial material may be filled based on a spin-on process. In some aspects, the sacrificial material may include silicon nitride (SiN), which may be highly selective over Si, SiGe, and/or silicon oxide during certain etch processes. In some aspects, the structure 500D may correspond to the resulting structure of stage 420 in FIG. 4A.

As shown in FIG. 5E, a structure 500E is formed based on the structure 500D by performing a recess process to remove excessive sacrificial material to at least expose the sidewalls of the multilayer structure of the gate stacks 502, 504, and 506 that correspond to channel members thereof. The remaining of the filled sacrificial material from the structure 500D becomes sacrificial structures 522 and 528. In some aspects, the sacrificial structures 522 and 528 may be used as placeholders for the backside conductive structures 342 and 348. In some aspects, the structure 500E may correspond to the resulting structure of stage 422 in FIG. 4A.

As shown in FIG. 5F, a structure 500F is formed based on the structure 500E by performing the operations corresponding to stages 425, 435, and 445. As a result, the epitaxial stop layer 362 is formed, the epitaxial layer 364 is formed, the gate stacks 302, 304, and 306 with HK metal gate structures and channel structures are formed, and the corresponding S/D structures (e.g., S/D structures 322, 324, 326, and 328) are formed. In some aspects, the structure 500F may correspond to the resulting structure of stage 445 in FIG. 4A.

As shown in FIG. 5G, a structure 500G is formed based on the structure 500F. In some aspects, one or more of FEOL process, MOL process, or BEOL process may be performed on the structure 500F from the front side, and the wafer on which the structure 500F is formed may be bonded to a carrier and flipped for various further processes from the back side. In some aspects, a substrate thin-down process may be performed from the back side to remove at least a portion of the substrate 508, and the rest of the substrate 508 may be further removed during a silicon pillar removal process. Afterwards, the backside dielectric layer 382 may be formed. In some aspects, the backside dielectric layer 382 may include silicon oxide. In some aspects, the structure 500G may correspond to the resulting structure of stage 475 in FIG. 4B.

As shown in FIG. 5H, a structure 500H is formed based on the structure 500G by removing the sacrificial structures 522 and 528, and then performing an epi stop punch through process to remove a portion of the epitaxial stop layer 362 under the S/D structures 322, 324, and 328 and exposed after the removal of the sacrificial structures 522 and 528. As shown in FIG. 5H, after the sacrificial removal process and the epi stop punch through process, backside openings 532 and 538 are defined. In some aspects, the backside openings 532 and 538 may correspond to the positions where the backside conductive structures 342 and 348 will be formed. In some aspects, the structure 500H may correspond to the resulting structure of stage 480 in FIG. 4B.

As shown in FIG. 5I, a structure 500I is formed based on the structure 500H by filling the backside openings 532 and 538 with a conductive or metallic material to form the backside conductive structures 342 and 348. In some aspects, the conductive or metallic material may include tungsten, cobalt, molybdenum, ruthenium, or a combination thereof. In some aspects, the structure 500H may correspond to the resulting structure of stage 482 in FIG. 4B. In some aspects, the structure 500H may correspond to the structure 300B in FIGS. 3B-3D.

As shown in FIG. 5J, a structure 500J may be formed based on the structure 500I by forming one or more ILD layers 542 and 546 and one or more backside conductive structures 552, 554, and 556 based on one or more backside metallization processes. In some aspects, the backside conductive structures 552 and 554 may be formed within the ILD layer 542, and the backside conductive structure 556 may be formed within the ILD layer 546. In some aspects, the backside conductive structure 556 may be a backside power line; the backside conductive structure 552 may be a contact connecting the backside conductive structure 342 with the backside conductive structure 556. Also, the backside conductive structure 554 may be a backside signal line connecting the backside conductive structure 348 to another backside conductive structure formed within the backside dielectric layer 382. In some aspects, the structure 500J may correspond to the resulting structure of stage 495 in FIG. 4B.

In some aspects, due to self-aligned nature, the backside conductive structures (e.g., the backside conductive structures 342 and 348) may fill up the space between the bottom inner spacers between gate stacks. In some aspects, the benefits of the self-aligned scheme may include increased process margin for performing contact open and preventing contact-to-gate short defect. In some aspects, the benefits of the self-aligned scheme may include reduced contact resistance due to the increased size of the backside conductive structures.

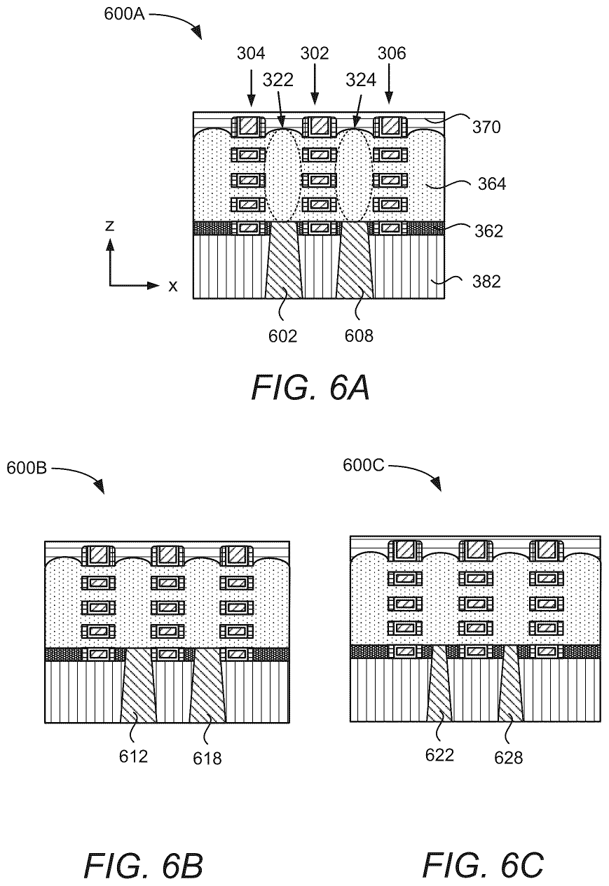

FIGS. 6A-6C illustrate some advantages of the present disclosure based on other structure examples, according to aspects of the disclosure. The elements in FIGS. 6A-6C that are the same or similar to those in FIGS. 3B-3C are given the same reference numbers, and the detailed description thereof may be omitted.

As shown in FIG. 6A, compared to the structure 300B, the structure 600A shown in FIG. 6A may have backside conductive structures 602 and 608 (corresponding to the backside conductive structures 342 and 348) formed based on directly etching the backside dielectric layer 382 from the back side. Accordingly, in some aspects, a first width of an upper portion of the backside conductive structure (e.g., the backside conductive structure 602 or 608) in the second direction (e.g., the x direction) may be less than a second width of a lower portion of the backside conductive structure in the second direction. In some aspects, the backside conductive structures 602 and 608 may be non-self-aligned or direct-print conductive structures. In FIG. 6A, the conductive structures 602 and 608 are each positioned in the middle of two adjacent gate stacks 302/304 and 302/306.

However, in reality, the manufacturing process may have process variations, critical dimension limitations, and/or mask misalignment tolerances. In some aspects, non-self-aligned, or direct-print contact scheme will have to manage the yield window carefully. For example, as shown in FIG. 6B, the structure 600B includes backside conductive structure 612 and 618 corresponding to the backside conductive structure 602 and 608. respectively. In this example, because of misalignment of the masks during the corresponding lithographic process, the backside conductive structure 612 and 618 may be shifted to the right in comparison to their nominal position as the backside conductive structure 602 and 608 in FIG. 6A. The example as shown in FIG. 6B may have an increased risk of causing the contact-to-gate short defect.

In some examples, to lower the risk of causing the contact-to-gate short defect, the dimensions of the backside conductive structures may be reduced. For example, the structure 600C in FIG. 6C includes backside conductive structure 622 and 628 corresponding to the backside conductive structure 602 and 608, respectively. In this example, the backside conductive structures 622 and 628 have a reduced size in comparison to their counterparts in FIG. 6A. While the risk of causing the contact-to-gate short defect may be reduced, the smaller size of the backside conductive structures 622 and 628 further increases the contact resistance.

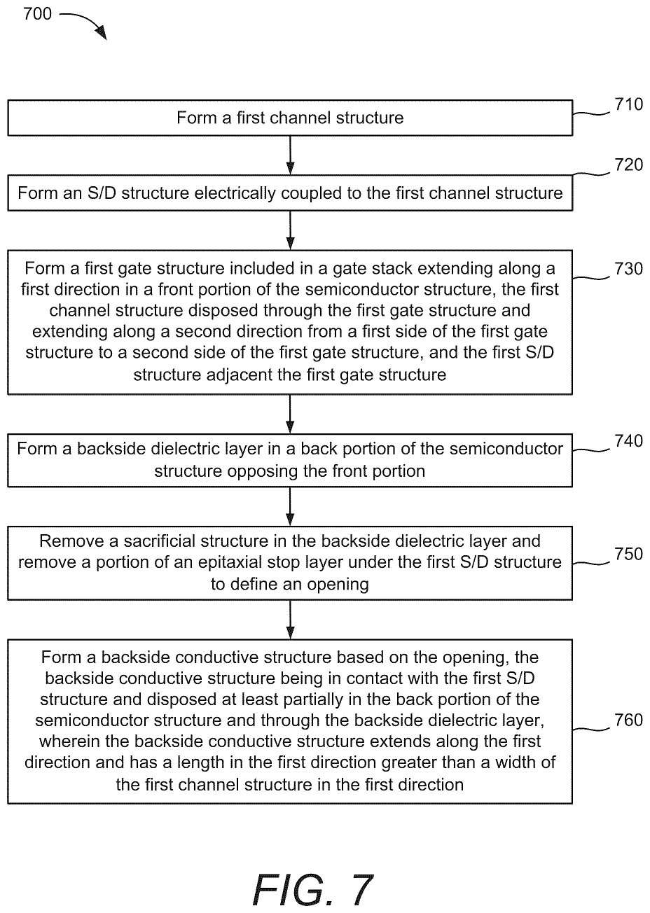

FIG. 7 illustrates a method 700 for manufacturing a semiconductor structure (such as the semiconductor structure examples depicted in FIGS. 3B-3D), according to aspects of the disclosure.

At operation 710, a first channel structure (e.g., the channel structure within the gate stack 302 in the active area 312) is formed. In some aspects, the first channel structure may be formed based on stages 405 and 415 in FIG. 4A, and the resulting structure may correspond to the structure 500A in FIG. 5A.

At operation 720, a first S/D structure (e.g., the S/D structure 324) is formed. In some aspects, the first S/D structure may be electrically coupled to the first channel structure. In some aspects, the first channel structure may be formed based on stage 425 in FIG. 4A. In some aspects, between operations 710 and 720, operations corresponding to stages 418-422 in FIG. 4A and/or the structures in FIGS. 5B-5E may be performed in order to form a sacrificial structure (e.g., the backside sacrificial structure 528).

At operation 730, a first gate structure (e.g., the gate structure based on the gate stack 302 in the active area 312) included in a gate stack (e.g., the gate stack 302) extending along a first direction (e.g., the y direction in FIG. 3B) in a front portion of the semiconductor structure. In some aspects, the first channel structure may be disposed through the first gate structure and extend along a second direction (e.g., the x direction in FIG. 3B) from a first side of the first gate structure to a second side of the first gate structure. In some aspects, the first S/D structure may be adjacent the first gate structure. In some aspects, the first gate structure may be formed based on stages 435 and 445 in FIG. 4A, and the resulting structure may correspond to the structure 500F in FIG. 5F.

In some aspects, the first channel structure may include one or more channel members. In some aspects, the forming the first gate structure may include forming one or more gate dielectric structures on the respective one or more channel members, and forming a gate electrode structure, where the one or more gate dielectric structures may be between the gate electrode structure and the respective one or more channel members. In some aspects, the one or more channel members may include a plurality of nanowires or nanosheets.

At operation 740, a backside dielectric layer (e.g., the backside dielectric layer 382) is formed in a back portion of the semiconductor structure opposing the front portion. As a result, the sacrificial structure (e.g., the backside sacrificial structure 528) is now at least partially in the backside dielectric layer. In some aspects, the backside dielectric layer may be formed based on stages 465 and 475 in FIG. 4B, and the resulting structure may correspond to the structure 500G in FIG. 5G.

At operation 750, the sacrificial structure (e.g., the backside sacrificial structure 528) in the backside dielectric layer is removed. Also, a portion of an epitaxial stop layer (e.g., the epitaxial stop layer 362) under the first S/D structure (the S/D structure 324) is removed. The removal of the sacrificial structure and the removal of the portion of the epitaxial stop layer may define an opening (e.g., the opening 538). In some aspects, the backside dielectric layer may be formed based on stage 480 in FIG. 4B, and the resulting structure may correspond to the structure 500H in FIG. 5H.

In some aspects, operation 710 may include forming a second channel structure; operation 720 may include forming a second S/D structure electrically coupled to the second channel structure; and operation 730 may include forming a second gate structure included in the gate stack in the front portion of the semiconductor structure. In some aspects, the second gate structure may be offset from the first gate structure in the first direction. In some aspects, the second channel structure may be disposed through the second gate structure and extend along the second direction from a third side of the second gate structure to a fourth side of the second gate structure. In some aspects, the second S/D structure may be adjacent the second gate structure. In some aspects, the first S/D structure has a first doping type, and the second S/D structure has a second doping type different from the first doping type.

In some aspects, the opening formed at operation 750 may be defined such that the backside conductive structure formed based on the opening extends along the first direction at least from the first S/D structure to a middle point between the first S/D structure and the second S/D structure. In some aspects, the opening may be defined such that the backside conductive structure formed based on the opening extends along the first direction at least from the first S/D structure to a middle point between the first S/D structure and the second S/D structure. In some aspects, the opening may be defined such that the backside conductive structure formed based on the opening extends along the first direction from the first S/D structure to the second S/D structure, and the backside conductive structure is formed to be in contact with the second S/D structure.

At operation 760, a backside conductive structure (e.g., the backside conductive structure 348) may be formed based on the opening. In some aspects, the backside conductive structure may be formed by filling the opening with a conductive or metallic material. In some aspects, the backside conductive structure may include tungsten, cobalt, molybdenum, ruthenium, or a combination thereof. In some aspects, the backside conductive structure may be in contact with the first S/D structure and disposed at least partially in the back portion of the semiconductor structure and through the backside dielectric layer. In some aspects, the backside conductive structure may extend along the first direction and has a length (e.g., the length L2 in FIG. 3B) in the first direction greater than a width (e.g., the width W in FIG. 3B) of the first channel structure in the first direction. In some aspects, the backside conductive structure may be formed based on stage 482 in FIG. 4B, and the resulting structure may correspond to the structure 300B in FIGS. 3B-3D and/or the structure 5001 in FIG. 5I.

In some aspects, an upper portion of the backside conductive structure may be in contact with a bottom inner spacer of the first gate structure and a bottom inner spacer of another gate structure that is offset from the first gate structure in the second direction. In some aspects, a first width of an upper portion of the backside conductive structure in the second direction may be greater than a second width of a lower portion of the backside conductive structure in the second direction.

In some aspects, after operation 760, a metallization structure may be formed in the back portion of the semiconductor structure, where the metallization structure may be under and in contact with the backside conductive structure at a contact area of the backside conductive structure. In some aspects, the contact area of the backside conductive structure may be offset from and non-overlapping with the first channel structure in the first direction.

A technical advantage of the method 700 is the formation of the backside conductive structures (e.g., BSCs and BSCLIs) based on a self-aligned scheme in order to reduce contact resistance due to the increased size of the self-aligned backside conductive structures and/or to increase the process margin for forming the self-aligned backside conductive structures.

The foregoing disclosed devices and functionalities may be designed and stored in computer files (e.g., register-transfer level (RTL), Geometric Data Stream (GDS), Gerber, and the like) stored on computer-readable media. Some or all such files may be provided to fabrication handlers who fabricate devices based on such files. Resulting products may include various components, including semiconductor wafers that are then cut into semiconductor die and packaged into semiconductor packages, integrated devices, package on package devices, system-on-chip devices, and the like, which may then be employed in the various devices described herein.

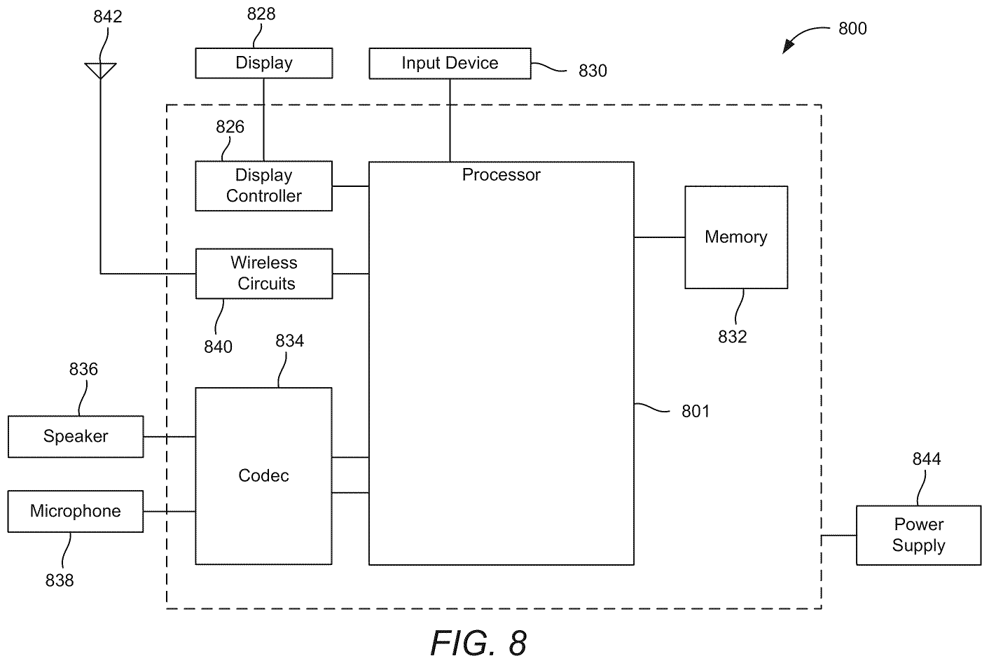

FIG. 8 illustrates a mobile device 800, according to aspects of the disclosure. In some aspects, the mobile device 800 may be implemented by including one or more IC devices manufactured based on the examples described in this disclosure.

In some aspects, mobile device 800 may be configured as a wireless communication device. As shown, mobile device 800 includes processor 801. Processor 801 may be communicatively coupled to memory 832 over a link, which may be a die-to-die or chip-to-chip link. Mobile device 800 also includes display 828 and display controller 826, with display controller 826 coupled to processor 801 and to display 828. The mobile device 800 may include input device 830 (e.g., physical, or virtual keyboard), power supply 844 (e.g., battery), speaker 836, microphone 838, and wireless antenna 842. In some aspects, the power supply 844 may directly or indirectly provide the supply voltage for operating some or all of the components of the mobile device 800.

In some aspects, FIG. 8 may include coder/decoder (CODEC) 834 (e.g., an audio and/or voice CODEC) coupled to processor 801; speaker 836 and microphone 838 coupled to CODEC 834; and wireless circuits 840 (which may include a modem, RF circuitry, filters, etc.) coupled to wireless antenna 842 and to processor 801.

In some aspects, one or more of processor 801, display controller 826, memory 832, CODEC 834, and wireless circuits 840 may include one or more IC devices including semiconductor structures manufactured according to the examples described in this disclosure.

It should be noted that although FIG. 8 depicts a mobile device 800, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

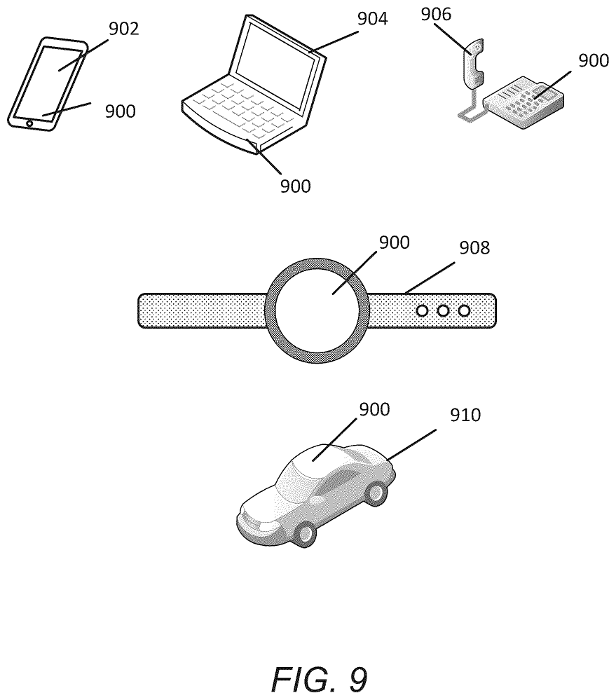

FIG. 9 illustrates various electronic devices that may be integrated with any of the aforementioned devices, semiconductor devices, integrated circuit (IC) packages, integrated circuit (IC) devices, semiconductor devices, integrated circuits, electronic components, interposer packages, package-on-package (PoP), System in Package (SiP), or System on Chip (SoC). For example, a mobile phone device 902, a laptop computer device 904, a fixed location terminal device 906, a wearable device 908, or automotive vehicle 910 may include a semiconductor device 900 (e.g., including semiconductor structures 100, 200, and 500) as described herein. The devices 902, 904, 906 and 908 and the vehicle 910 illustrated in FIG. 9 are merely exemplary. Other apparatuses or devices may also feature the semiconductor device 900 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1 through 9 may be rearranged and/or combined into a single component, process, feature, or function or incorporated in several components, processes, or functions. Additional elements, components, processes, and/or functions may also be added without departing from the disclosure. In some implementations, FIGS. 1 through 9 and the corresponding description may be used to manufacture, create, provide, and/or produce integrated devices. In some implementations, a device may include a die, an integrated device, a die package, an IC, a device package, an IC package, a wafer, a semiconductor device, a system in package (SiP), a system on chip (SoC), a package on package (PoP) device, and the like.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. UEs can be embodied by any of a number of types of devices including but not limited to printed circuit (PC) cards, compact flash devices, external or internal modems, wireless or wireline phones, smartphones, tablets, consumer tracking devices, asset tags, and so on.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth® (BT), Bluetooth® Low Energy (BLE), IEEE 802.11 (WiFi), and IEEE 802.15.4 (Zigbee®/Thread) or other protocols that may be used in a wireless communications network or a data communications network.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. A semiconductor structure, comprising: a gate stack extending along a first direction in a front portion of the semiconductor structure, the gate stack including a first gate structure; a first channel structure disposed through the first gate structure and extending along a second direction from a first side of the first gate structure to a second side of the first gate structure; a first source/drain (S/D) structure adjacent the first gate structure and electrically coupled to the first channel structure; a backside dielectric layer disposed in a back portion of the semiconductor structure opposing the front portion; and a backside conductive structure in contact with the first S/D structure and disposed at least partially in the back portion of the semiconductor structure and through the backside dielectric layer, wherein the backside conductive structure extends along the first direction and has a length in the first direction greater than a width of the first channel structure in the first direction.

Clause 2. The semiconductor structure of clause 1, further comprising: a second channel structure disposed through a second gate structure included in the gate stack and extending along the second direction from a third side of the second gate structure to a fourth side of the second gate structure, and the second gate structure being offset from the first gate structure in the first direction; and a second S/D structure adjacent the second gate structure and electrically coupled to the second channel structure, wherein the first S/D structure has a first doping type, and the second S/D structure has a second doping type different from the first doping type.

Clause 3. The semiconductor structure of clause 2, wherein: the backside conductive structure extends along the first direction at least from the first S/D structure to a middle point between the first S/D structure and the second S/D structure.

Clause 4. The semiconductor structure of clause 3, wherein: the backside conductive structure extends along the first direction at least from the first S/D structure to the second S/D structure and is in contact with the second S/D structure.

Clause 5. The semiconductor structure of any of clauses 1 to 4, wherein: the first channel structure comprises one or more channel members, and the first gate structure comprises: a gate electrode structure, and one or more gate dielectric structures between the gate electrode structure and the respective one or more channel members.

Clause 6. The semiconductor structure of clause 5, wherein: the one or more channel members comprise a plurality of nanowires or nanosheets.

Clause 7. The semiconductor structure of any of clauses 1 to 6, wherein: an upper portion of the backside conductive structure is in contact with a bottom inner spacer of the first gate structure and a bottom inner spacer of another gate structure that is offset from the first gate structure in the second direction.

Clause 8. The semiconductor structure of clause 7, wherein: a first width of the upper portion of the backside conductive structure in the second direction is greater than a second width of a lower portion of the backside conductive structure in the second direction.

Clause 9. The semiconductor structure of any of clauses 1 to 8, further comprising: a metallization structure disposed in the back portion of the semiconductor structure, and under and coupled to the backside conductive structure through a backside via, wherein the backside via is offset from and non-overlapping with the first channel structure in the first direction.

Clause 10. The semiconductor structure of any of clauses 1 to 9, wherein: the backside conductive structure comprises tungsten, cobalt, molybdenum, ruthenium, or a combination thereof.

Clause 11. A method of manufacturing a semiconductor structure, comprising: forming a first channel structure; forming a first source/drain (S/D) structure electrically coupled to the first channel structure; forming a first gate structure included in a gate stack extending along a first direction in a front portion of the semiconductor structure, the first channel structure disposed through the first gate structure and extending along a second direction from a first side of the first gate structure to a second side of the first gate structure, and the first S/D structure adjacent the first gate structure; forming a backside dielectric layer in a back portion of the semiconductor structure opposing the front portion; removing a sacrificial structure in the backside dielectric layer and removing a portion of an epitaxial stop layer under the first S/D structure to define an opening; and forming a backside conductive structure based on the opening, the backside conductive structure being in contact with the first S/D structure and disposed at least partially in the back portion of the semiconductor structure and through the backside dielectric layer, wherein the backside conductive structure extends along the first direction and has a length in the first direction greater than a width of the first channel structure in the first direction.

Clause 12. The method of clause 11, further comprising: forming a second channel structure; forming a second S/D structure electrically coupled to the second channel structure; and forming a second gate structure included in the gate stack in the front portion of the semiconductor structure, the second gate structure being offset from the first gate structure in the first direction, and the second channel structure disposed through the second gate structure and extending along the second direction from a third side of the second gate structure to a fourth side of the second gate structure, and the second S/D structure adjacent the second gate structure, wherein the first S/D structure has a first doping type, and the second S/D structure has a second doping type different from the first doping type.

Clause 13. The method of clause 12, wherein: the opening is defined such that the backside conductive structure formed based on the opening extends along the first direction at least from the first S/D structure to a middle point between the first S/D structure and the second S/D structure.

Clause 14. The method of clause 13, wherein: the opening is defined such that the backside conductive structure formed based on the opening extends along the first direction from the first S/D structure to the second S/D structure, and the backside conductive structure is formed to be in contact with the second S/D structure.

Clause 15. The method of any of clauses 11 to 14, wherein: the first channel structure comprises one or more channel members, and the forming the first gate structure comprises: forming one or more gate dielectric structures on the respective one or more channel members; and forming a gate electrode structure, the one or more gate dielectric structures being between the gate electrode structure and the respective one or more channel members.

Clause 16. The method of clause 15, wherein: the one or more channel members comprise a plurality of nanowires or nanosheets.

Clause 17. The method of any of clauses 11 to 16, wherein an upper portion of the backside conductive structure is in contact with a bottom inner spacer of the first gate structure and a bottom inner spacer of another gate structure that is offset from the first gate structure in the second direction.

Clause 18. The method of clause 17, wherein a first width of the upper portion of the backside conductive structure in the second direction is greater than a second width of a lower portion of the backside conductive structure in the second direction.

Clause 19. The method of any of clauses 11 to 18, further comprising: forming a metallization structure in the back portion of the semiconductor structure, and under and in contact with the backside conductive structure at a contact area of the backside conductive structure, wherein the contact area of the backside conductive structure is offset from and non-overlapping with the first channel structure in the first direction.

Clause 20. The method of any of clauses 11 to 19, wherein: the backside conductive structure comprises tungsten, cobalt, molybdenum, ruthenium, or a combination thereof.

Clause 21. An electronic device, comprising: an integrated circuit device including a semiconductor structure, and the semiconductor structure comprising: a gate stack extending along a first direction in a front portion of the semiconductor structure, the gate stack including a first gate structure; a first channel structure disposed through the first gate structure and extending along a second direction from a first side of the first gate structure to a second side of the first gate structure; a first source/drain (S/D) structure adjacent the first gate structure and electrically coupled to the first channel structure; a backside dielectric layer disposed in a back portion of the semiconductor structure opposing the front portion; and a backside conductive structure in contact with the first S/D structure and disposed at least partially in the back portion of the semiconductor structure and through the backside dielectric layer, wherein the backside conductive structure extends along the first direction and has a length in the first direction greater than a width of the first channel structure in the first direction.

Clause 22. The electronic device of clause 21, further comprising: a second channel structure disposed through a second gate structure included in the gate stack and extending along the second direction from a third side of the second gate structure to a fourth side of the second gate structure, and the second gate structure being offset from the first gate structure in the first direction; and a second S/D structure adjacent the second gate structure and electrically coupled to the second channel structure, wherein the first S/D structure has a first doping type, and the second S/D structure has a second doping type different from the first doping type.

Clause 23. The electronic device of clause 22, wherein: the backside conductive structure extends along the first direction at least from the first S/D structure to a middle point between the first S/D structure and the second S/D structure.

Clause 24. The electronic device of clause 23, wherein: the backside conductive structure extends along the first direction at least from the first S/D structure to the second S/D structure and is in contact with the second S/D structure.

Clause 25. The electronic device of any of clauses 21 to 24, wherein: the first channel structure comprises one or more channel members, and the first gate structure comprises: a gate electrode structure, and one or more gate dielectric structures between the gate electrode structure and the respective one or more channel members.

Clause 26. The electronic device of clause 25, wherein: the one or more channel members comprise a plurality of nanowires or nanosheets.

Clause 27. The electronic device of any of clauses 21 to 26, wherein: an upper portion of the backside conductive structure is in contact with a bottom inner spacer of the first gate structure and a bottom inner spacer of another gate structure that is offset from the first gate structure in the second direction.

Clause 28. The electronic device of clause 27, wherein: a first width of the upper portion of the backside conductive structure in the second direction is greater than a second width of a lower portion of the backside conductive structure in the second direction.

Clause 29. The electronic device of any of clauses 21 to 28, further comprising: a metallization structure disposed in the back portion of the semiconductor structure, and under and coupled to the backside conductive structure through a backside via, wherein the backside via is offset from and non-overlapping with the first channel structure in the first direction.

Clause 30. The electronic device of any of clauses 21 to 29, wherein: the backside conductive structure comprises tungsten, cobalt, molybdenum, ruthenium, or a combination thereof.

Clause 31. The electronic device of any of clauses 21 to 30, wherein the electronic device comprises a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Nothing stated or illustrated depicted in this application is intended to dedicate any component, action, feature, benefit, advantage, or equivalent to the public, regardless of whether the component, action, feature, benefit, advantage, or the equivalent is recited in the claims.

It should furthermore be noted that methods, systems, and apparatus disclosed in the description or in the claims can be implemented by a device comprising means for performing the respective actions and/or functionalities of the methods disclosed. Furthermore, While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order.

Further, no component, function, action, or instruction described or claimed herein should be construed as critical or essential unless explicitly described as such. Furthermore, as used herein, the terms “set,” “group,” and the like are intended to include one or more items and may be used interchangeably with “at least one,” “one or more,” and the like. Also, as used herein, the terms “has,” “have,” “having,” and the like are intended to be open-ended terms that do not limit an element that they modify (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more items and may be used interchangeably with “at least one,” “one or more,” and the like. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination. In some examples, an individual action can be subdivided into one or more sub-actions or contain one or more sub-actions. Such sub-actions can be contained in the disclosure of the individual action and be part of the disclosure of the individual action.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A semiconductor structure, comprising:
a gate stack extending along a first direction in a front portion of the semiconductor structure, the gate stack including a first gate structure;
a first channel structure disposed through the first gate structure and extending along a second direction from a first side of the first gate structure to a second side of the first gate structure;
a first source/drain (S/D) structure adjacent the first gate structure and electrically coupled to the first channel structure;
a backside dielectric layer disposed in a back portion of the semiconductor structure opposing the front portion; and
a backside conductive structure in contact with the first S/D structure and disposed at least partially in the back portion of the semiconductor structure and through the backside dielectric layer,
wherein the backside conductive structure extends along the first direction and has a length in the first direction greater than a width of the first channel structure in the first direction.

2. The semiconductor structure of claim 1, further comprising:
a second channel structure disposed through a second gate structure included in the gate stack and extending along the second direction from a third side of the second gate structure to a fourth side of the second gate structure, and the second gate structure being offset from the first gate structure in the first direction; and
a second S/D structure adjacent the second gate structure and electrically coupled to the second channel structure,
wherein the first S/D structure has a first doping type, and the second S/D structure has a second doping type different from the first doping type.

3. The semiconductor structure of claim 2, wherein:
the backside conductive structure extends along the first direction at least from the first S/D structure to a middle point between the first S/D structure and the second S/D structure.

4. The semiconductor structure of claim 3, wherein:
the backside conductive structure extends along the first direction at least from the first S/D structure to the second S/D structure and is in contact with the second S/D structure.

5. The semiconductor structure of claim 1, wherein:
the first channel structure comprises one or more channel members, and
the first gate structure comprises:
a gate electrode structure, and
one or more gate dielectric structures between the gate electrode structure and the respective one or more channel members.

6. The semiconductor structure of claim 5, wherein:
the one or more channel members comprise a plurality of nanowires or nanosheets.

7. The semiconductor structure of claim 1, wherein:
an upper portion of the backside conductive structure is in contact with a bottom inner spacer of the first gate structure and a bottom inner spacer of another gate structure that is offset from the first gate structure in the second direction.

8. The semiconductor structure of claim 7, wherein:
a first width of the upper portion of the backside conductive structure in the second direction is greater than a second width of a lower portion of the backside conductive structure in the second direction.

9. The semiconductor structure of claim 1, further comprising:
a metallization structure disposed in the back portion of the semiconductor structure, and under and coupled to the backside conductive structure through a backside via,
wherein the backside via is offset from and non-overlapping with the first channel structure in the first direction.

10. The semiconductor structure of claim 1, wherein:
the backside conductive structure comprises tungsten, cobalt, molybdenum, ruthenium, or a combination thereof.

11. A method of manufacturing a semiconductor structure, comprising:
forming a first channel structure;
forming a first source/drain (S/D) structure electrically coupled to the first channel structure;
forming a first gate structure included in a gate stack extending along a first direction in a front portion of the semiconductor structure, the first channel structure disposed through the first gate structure and extending along a second direction from a first side of the first gate structure to a second side of the first gate structure, and the first S/D structure adjacent the first gate structure;
forming a backside dielectric layer in a back portion of the semiconductor structure opposing the front portion;
removing a sacrificial structure in the backside dielectric layer and removing a portion of an epitaxial stop layer under the first S/D structure to define an opening; and
forming a backside conductive structure based on the opening, the backside conductive structure being in contact with the first S/D structure and disposed at least partially in the back portion of the semiconductor structure and through the backside dielectric layer,
wherein the backside conductive structure extends along the first direction and has a length in the first direction greater than a width of the first channel structure in the first direction.

12. The method of claim 11, further comprising:
forming a second channel structure;
forming a second S/D structure electrically coupled to the second channel structure; and
forming a second gate structure included in the gate stack in the front portion of the semiconductor structure, the second gate structure being offset from the first gate structure in the first direction, and the second channel structure disposed through the second gate structure and extending along the second direction from a third side of the second gate structure to a fourth side of the second gate structure, and the second S/D structure adjacent the second gate structure,
wherein the first S/D structure has a first doping type, and the second S/D structure has a second doping type different from the first doping type.

13. The method of claim 12, wherein:
the opening is defined such that the backside conductive structure formed based on the opening extends along the first direction at least from the first S/D structure to a middle point between the first S/D structure and the second S/D structure.

14. The method of claim 13, wherein:
the opening is defined such that the backside conductive structure formed based on the opening extends along the first direction from the first S/D structure to the second S/D structure, and
the backside conductive structure is formed to be in contact with the second S/D structure.

15. The method of claim 11, wherein:
the first channel structure comprises one or more channel members, and
the forming the first gate structure comprises:
forming one or more gate dielectric structures on the respective one or more channel members; and
forming a gate electrode structure, the one or more gate dielectric structures being between the gate electrode structure and the respective one or more channel members.

16. The method of claim 15, wherein:
the one or more channel members comprise a plurality of nanowires or nanosheets.

17. The method of claim 11, wherein:
an upper portion of the backside conductive structure is in contact with a bottom inner spacer of the first gate structure and a bottom inner spacer of another gate structure that is offset from the first gate structure in the second direction.

18. The method of claim 17, wherein:
a first width of the upper portion of the backside conductive structure in the second direction is greater than a second width of a lower portion of the backside conductive structure in the second direction.

19. The method of claim 11, further comprising:
forming a metallization structure in the back portion of the semiconductor structure, and under and in contact with the backside conductive structure at a contact area of the backside conductive structure,
wherein the contact area of the backside conductive structure is offset from and non-overlapping with the first channel structure in the first direction.

20. The method of claim 11, wherein:
the backside conductive structure comprises tungsten, cobalt, molybdenum, ruthenium, or a combination thereof.

21. An electronic device, comprising:
an integrated circuit device including a semiconductor structure, and the semiconductor structure comprising:
a gate stack extending along a first direction in a front portion of the semiconductor structure, the gate stack including a first gate structure;
a first channel structure disposed through the first gate structure and extending along a second direction from a first side of the first gate structure to a second side of the first gate structure;
a first source/drain (S/D) structure adjacent the first gate structure and electrically coupled to the first channel structure;
a backside dielectric layer disposed in a back portion of the semiconductor structure opposing the front portion; and
a backside conductive structure in contact with the first S/D structure and disposed at least partially in the back portion of the semiconductor structure and through the backside dielectric layer,
wherein the backside conductive structure extends along the first direction and has a length in the first direction greater than a width of the first channel structure in the first direction.

22. The electronic device of claim 21, further comprising:
a second channel structure disposed through a second gate structure included in the gate stack and extending along the second direction from a third side of the second gate structure to a fourth side of the second gate structure, and the second gate structure being offset from the first gate structure in the first direction; and
a second S/D structure adjacent the second gate structure and electrically coupled to the second channel structure,
wherein the first S/D structure has a first doping type, and the second S/D structure has a second doping type different from the first doping type.

23. The electronic device of claim 22, wherein:
the backside conductive structure extends along the first direction at least from the first S/D structure to a middle point between the first S/D structure and the second S/D structure.

24. The electronic device of claim 23, wherein:
the backside conductive structure extends along the first direction at least from the first S/D structure to the second S/D structure and is in contact with the second S/D structure.

25. The electronic device of claim 21, wherein:
the first channel structure comprises one or more channel members, and
the first gate structure comprises:
a gate electrode structure, and
one or more gate dielectric structures between the gate electrode structure and the respective one or more channel members.

26. The electronic device of claim 25, wherein:
the one or more channel members comprise a plurality of nanowires or nanosheets.

27. The electronic device of claim 21, wherein:
an upper portion of the backside conductive structure is in contact with a bottom inner spacer of the first gate structure and a bottom inner spacer of another gate structure that is offset from the first gate structure in the second direction.

28. The electronic device of claim 27, wherein:
a first width of the upper portion of the backside conductive structure in the second direction is greater than a second width of a lower portion of the backside conductive structure in the second direction.

29. The electronic device of claim 21, further comprising:
a metallization structure disposed in the back portion of the semiconductor structure, and under and coupled to the backside conductive structure through a backside via,
wherein the backside via is offset from and non-overlapping with the first channel structure in the first direction.

30. The electronic device of claim 21, wherein:
the backside conductive structure comprises tungsten, cobalt, molybdenum, ruthenium, or a combination thereof.

31. The electronic device of claim 21, wherein the electronic device comprises a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.
